(19) United States
(12) Patent Application Publication
(10) Pub. No.: US 2026/0305031 A1
(43) Pub. Date: Oct. 1, 2026

(54) OPTOELECTRONIC DEVICE

(71) Applicant: AMS-OSRAM AG, Premstaetten (AT)

(72) Inventors: Amirhossein GHODS, Darien, IL (US); David SANDQUIST, St. Paul, MN (US); Jyothy CHEMMACHERILJOBY, Burnsville, MN (US); Karim TATAH, Eden Prairie, MN (US)

(21) Appl. No.: 19/477,815

(22) PCT Filed: Apr. 12, 2024
(86) PCT No.: PCT/EP2024/059927

§ 371 Date: Oct. 23, 2025

Related U.S. Application Data
(60) Provisional application No. 63/498,533, filed on Apr. 27, 2023.

(51) Int. Cl. H10H 29/24; H10F 30/225; H10F 39/90

(52) U.S. Cl. CPC H10H 29/24; H10F 39/90; H10F 30/225

(57) ABSTRACT

Please CANCEL the abstract and replace it with the following. No new matter is added. Disclosed herein is an optoelectronic device that includes an emitter operated with an electrical input voltage and configured to emit electromagnetic radiation during operation. It further includes a receiver that includes at least one photodiode, the receiver being configured to convert electromagnetic radiation emitted by the emitter to an output voltage. It further includes an optical sensor that includes at least one avalanche photodiode, wherein the optical sensor is operated with the output voltage.

Also disclosed is a system for and a method of manufacturing the optoelectronic device.

An optoelectronic device is specified herein. Further, a system comprising the optoelectronic device and a method of manufacturing such optoelectronic device is provided.

### BACKGROUND OF THE INVENTION

In order to generate the biasing voltage required for an avalanche photodiode (or similarly a single-photon avalanche photodiode, SPAD) a charge pump circuit may be needed to place it in the reverse-breakdown condition and create the necessary electric field required for operation of the diode. The voltage sources (i. e., charge pumps) used for supplying single-photon avalanche photodiodes may be based on CMOS technology. Therefore, the charge pump circuit may be developed on a separate chip/circuit than the SPAD sensor. This adds to the total size of the SPAD module (i.e., SPAD array+charge pump) when used in a, for example LiDAR, solution. Moreover, the efficiency of these charge pumps is limited to the electronic components used in it and is, for example, 30-60%.

Additionally, most of the charge pumps are based on CMOS solutions implemented as integrated circuits with multiple transistors, resistors, and capacitors. These charge pump solutions can only generate certain levels of output voltage (few volts) as specified by the circuit design. In other words, as the required voltage for biasing the SPAD changes, the applicable charge pump that can also be used for that device also needs to be changed.

At least one objective is to specify an optoelectronic device, which can be designed to be particularly compact. At least one further objective is to specify an optoelectronic device which can provide flexibility with respect to operating voltages.

These objectives are achieved by the subject matter according to the independent claims. Advantageous embodiments and developments of the optoelectronic device are given in the dependent claims and are also disclosed by the following description and the drawings.

### SUMMARY OF THE INVENTION

According to an embodiment, an optoelectronic device comprises an emitter that is operated with an electrical input voltage and configured to emit electromagnetic radiation during operation.

The emitter is, for example, a component that generates electromagnetic radiation in the wavelength range between infrared radiation and UV radiation. In particular, the emitter can be configured to generate electromagnetic radiation in the wavelength range from at least 350 nm to at most 1100 nm, in particular in the wavelength range from at least 800 nm to at most 950 nm, during operation.

The emitter may comprise at least one surface emitter. In the present context, a surface emitter is understood to be a radiation-emitting component which emits the electromagnetic radiation generated during operation transversely, in particular perpendicularly, to a mounting surface on which the radiation-emitting component is mounted. In particular, the surface emitter may be a semiconductor device comprising an epitaxially grown semiconductor body. In particular, the direction in which the electromagnetic radiation is then emitted during operation may be parallel to a growth direction of the semiconductor body. The semiconductor body may, for example, be based on semiconductor materials such as In(Ga)N, In(Ga)AlP, (Al)GaAs, (In)GaAs. The surface emitter may be, for example, a light emitting diode or a laser diode, in particular a superluminescent diode or a VCSEL. In this context, the transmitter may contain a plurality of surface emitters, which may be connected to each other in series and/or in parallel. The input voltage of the emitter is then calculated accordingly from the voltages with which the surface emitters are operated. A laser diode may be operated in a pulsed mode or in a continuous wave (CW) mode.

According to an embodiment, the optoelectronic device further comprises a receiver comprising at least one photodiode, the receiver being configured to convert electromagnetic radiation emitted by the emitter to an output voltage.

The receiver is configured in particular to receive at least part of the electromagnetic radiation emitted by the emitter during operation and to convert at least part of the received electromagnetic radiation into electrical energy. In particular, the receiver can be tuned to the emitter in such a way that the receiver has a particularly high absorption for the electromagnetic radiation generated by the emitter. This can mean that the at least one photodiode comprised by the receiver has a bandgap energy that is smaller than the photon energy corresponding to the wavelength of the emitted electromagnetic radiation. The photodiode may comprise a semiconductor body having at least one detecting layer adapted to absorb electromagnetic radiation generated by the emitter during operation and to convert it into electrical energy. The at least one photodiode may be formed, for example, in the same material system as the at least one surface emitter or in a different material system. In particular, the receiver may comprise a plurality of photodiodes that may be connected together in series or in parallel. The output voltage of the receiver is then calculated accordingly from the voltage dropped across the individual photodiodes.

According to an embodiment, the optoelectronic device further comprises an optical sensor comprising at least one avalanche photodiode, wherein the optical sensor is operated with the output voltage.

The optical sensor may comprise further components for operating the at least one avalanche diode. For example, the optical circuit may comprise a control circuit for controlling the at least one avalanche diode. The optical sensor may form an imaging sensor. Thus, the optical sensor may comprise an array of avalanche photodiodes to capture an image. The optical sensor may thus further comprise a logic circuit for combining signals from different avalanche photodiodes. A time-to-digital converter may also be comprised by the optical sensor. An avalanche photodiode (APD) is a type of semiconductor photodetector that uses the avalanche effect to amplify the signal generated by incident electromagnetic radiation. When a photon is absorbed by the APD, it creates an electron-hole pair. Under certain conditions, these carriers can be accelerated by a high electric field, which results in additional carrier generation through impact ionization. This process causes an avalanche of carriers, leading to an amplification of the original signal. The electric field is provided by the output voltage generated by the receiver. The at least one avalanche photodiode may be formed, for example, in the same material system as the at least one photodiode or in a different material system. In particular, the at least one photodiode and the at least one avalanche photodiode are formed in the same material system in the same semiconductor process.

According to an embodiment, the optoelectronic device comprises an emitter that is operated with an electrical input voltage and configured to emit electromagnetic radiation during operation. It further comprises a receiver comprising at least one photodiode, the receiver being configured to convert electromagnetic radiation emitted by the emitter to an output voltage. It further comprises an optical sensor comprising at least one avalanche photodiode, wherein the optical sensor is operated with the output voltage.

The optoelectronic device described here is based on the following considerations, among others.

The emitter-receiver system described here can advantageously be used as or be an optical voltage transformer, OVT, also named optical voltage converter in the following. If the optical sensor was powered by a voltage source like a charge pump circuit to create the necessary electric field for operation of the avalanche diode, only certain levels of output voltage as specified by the circuit design could be generated. As the required voltage for biasing the avalanche diode changes, the applicable charge pump that can be used for that device also needs to be changed. The proposed solution is based on an optical voltage transformer technology that can generate any desired voltage (from a few volts to hundreds of volts) required for reverse biasing the avalanche diode. The wide range of output voltages that can be generated from the OVT, is something that no other CMOS based charge pump solution can provide. Smaller foot-print and lower cost is another advantage compared to charge pumps, especially as the required voltage for biasing the optical sensor increases. Further, less power consumption by the proposed OVT is expected as it only need to be operational when the emitter (e.g. a VCSEL) is turned on.

For example, the optoelectronic device described here combines semiconductor light emitters and photodiodes, i.e. photovoltaic cells (PV cells), to achieve a conversion from low to high voltage. For this purpose, one or more surface-emitting semiconductor lasers, light-emitting diodes or superluminescent diodes connected in parallel emit light on the low-voltage path, for example. Typical input voltages are 1 V, 3 V, 5 V, 8 V, 10 V or in between.

On the high-voltage side, which is galvanically separated from the low-voltage side, an array of series-connected photodiodes operating in photovoltaic mode collects the emitted light. Depending on the material used each photodiode generates a voltage on the order of 0.5-3 V and a current depending on the intensity of the incident light. By using a large number of photodiodes, which can all be connected in series on a very small scale, these individual voltages add up to a high total voltage that can exceed 10 V, 50 V, 100 V, 500 V.

The high output power of the emitter makes it possible to use only a single or a small number of surface emitters to illuminate the photodiodes, reducing the size and cost of the device on the emitter side. Further, the optoelectronic device is insensitive to external influences such as temperature fluctuations or electromagnetic fields.

According to an embodiment, the optoelectronic device further comprises a substrate, wherein the receiver and the optical sensor are integrated on a main surface of the substrate.

The substrate can be a semiconductor substrate. In particular, the substrate may comprise In (Ga) N, In (Ga) AlP, (Al) GaAs, (In) GaAs. The main surface extends in a main plane of extension of the substrate. That the receiver and the optical sensor are integrated on the main surface of the substrate can mean that they are formed on the main surface by a semiconductor process flow including epitaxial growth, chemical vapour deposition (CVD) and/or implantation steps etc. This can further mean that the receiver and the optical sensor are not mounted on the substrate but are integrally formed on the substrate to build a one-chip integration.

The on-chip integration of the optical sensor including the avalanche diode and the receiver is possible since they can be both based on a similar III-V epitaxial structure. This is different from conventional devices where the optical sensor (e. g. comprising SPADs based on III-V compound semiconductors) is implemented as separate chip arranged next to a charge pump circuit chip based on CMOS technology. Since both the photodiodes, i.e. PV cells, of the receiver and also the APDs, e.g. SPADs, of the optical sensor are based on similar III-V epitaxial structure, on-chip integration of both modules can be realized. In other words, both PV cells and SPAD pixels can be fabricated on one chip. This reduces the overall footprint of the optoelectronic device and the compactness is increased. In turn, a lower total weight/size for the optoelectronic device and simpler packaging can be achieved, which lowers the total cost per unit.

According to an embodiment, the optoelectronic device further comprises interconnects arranged on the main surface of the substrate and electrically connecting the receiver to the optical sensor for providing the output voltage to the optical sensor.

In other words, both PV cells and SPAD pixels can be fabricated on one chip and connected to each other by interconnects, which are also integrated on the main surface of the substrate. The interconnects can comprise a metal, e. g. gold, silver, copper, aluminum, titanium etc., or a metal alloy. The interconnects can connect electrical terminals (i.e. anode and cathode) of the receiver to a respective terminal of the optical sensor.

According to an embodiment of the optoelectronic device, the substrate is electrically insulating.

In particular, the substrate may comprise semi-insulating GaAs. Its resistivity can range from 10⁻⁶ Ω cm to about 10²² Ω cm, in particular from 10⁻³ Ω cm to 10⁸ Ω cm. Undoped GaAs can be made semi-insulating by the addition of dopants, e.g. either oxygen or chromium. Advantageously, the substrate is suited to integrated circuit fabrication. By means of the electrically insulating substrate short circuits can be prevented. It allows in particular the receiver to be integrally formed on the substrate. Further, semi-insulating GaAs has a high breakdown voltage, such that its high resistivity makes it useful for high-voltage applications.

According to an embodiment, the optoelectronic device further comprises an optical component configured to direct electromagnetic radiation emitted by the emitter towards the receiver.

The optical component may comprise any material that is transparent for electromagnetic radiation emitted by the emitter. In this context, “transparent” can mean a transparency of at least 80%, in particular at least 90%, for the wavelength of interest. In the simplest case the optical component comprises or is a gap between the emitter and the receiver. The gap can be filled with gas or air. The optical component can also comprise or be an interposer structure that is arranged between the emitter and the receiver. For example, the optical component is arranged on the receiver by means of an adhesive. The emitter can be arranged on the optical component by means of a further adhesive. In this case, the optical component can comprise, for example, glass or a plastic material. The optical component can also comprise or be a lens or lens array focusing electromagnetic radiation onto the receiver. With a focused cone of light, i.e. electromagnetic radiation, from the emitter, the distance and area of the receiver can also be compressed to a small scale. The optical component can also comprise or be a waveguide guiding electromagnetic radiation from the emitter to the receiver, such that as much as possible radiation can be converted by the receiver. In addition or alternatively, the optical component comprises or consists of a diffuser. In this case alignment between the emitter and the receiver can be more relaxed. It is further possible that the optical component comprises or is a reflector that reflects the emitted electromagnetic radiation onto the receiver.

According to an embodiment, the emitter and the receiver are configured as an optical voltage converter for operating the optical sensor.

This can mean that the emitter and the receiver form an OVT module to power up the optical sensor. As explained above, the emitter-receiver system described here can advantageously be used as or be an optical voltage converter. Thus, any desired voltage (from a few volts to hundreds of volts) required for reverse biasing the avalanche diode can be generated. The OVT further comes with a smaller foot-print and lower cost compared to charge pumps, especially as the required voltage for biasing the optical sensor increases.

According to an embodiment, the input voltage is less than the output voltage and the receiver comprises a plurality of photodiodes electrically connected in series.

In this case, it is possible, for example, that the emitter also comprises a plurality of light sources (e.g. surface emitters, in particular VCSELs), which are then connected in parallel with each other, for example. In particular, the input voltage of the emitter is lower than the output voltage of the receiver. The device is therefore arranged to convert a low input voltage into a high output voltage. For this purpose, the receiver may comprise a plurality of photodiodes, for example at least 10 photodiodes, in particular at least 50 or at least 100 individual photodiodes. The output voltage can be easily adjusted via the number of photodiodes connected in parallel and or in series to each other. In other words, the OVT can act as step-up voltage transformer during illumination.

According to an embodiment, the input voltage is larger than the output voltage and the emitter comprises a plurality of surface emitters electrically connected in series.

In particular, it is possible that the optoelectronic device comprises more surface emitters than photodiodes. Furthermore, it is possible that the device comprises a plurality of photodiodes at the receiver which are at least partially connected in parallel with each other. With this device it is possible to convert a high input voltage into a lower output voltage. In other words, the OVT can act as step-down voltage transformer during illumination.

According to an embodiment, the at least one avalanche photodiode of the optical sensor is a single-photon avalanche diode, SPAD.

A SPAD refers to an avalanche diode that is operated in Geiger mode, i.e. above the breakdown voltage. APDs including SPADs may require reverse bias voltages larger than 20 V to be in breakdown regime. The avalanche process leads to a large output pulse for each detected photon. SPADs offer several advantages over other detectors capable of detecting photons, including high sensitivity, high time resolution, low noise rate and low dark current rate. The optical sensor may additionally include electronics to enable the full SPAD operation (bias voltage, quench circuit etc.).

According to an embodiment, the receiver comprises an array of photodiodes. In an embodiment, the emitter comprises an array of surface emitter. In an embodiment, the emitter and the receiver are arranged on top of each other such that each photodiode is aligned with a respective surface emitter.

That the emitter and the receiver are arranged on top of each other can mean that they are stacked in a direction perpendicular to the main surface of the substrate. It can further mean that they are in direct contact or that an interposer structure is arranged in between. In particular, the optical component mentioned above can be arranged between the receiver and the emitter. The stack of receiver, optical component and emitter can form the optical voltage transformer module (OVT). That each photodiode is aligned to a respective surface emitter can mean that there is a 1:1 relationship between photodiodes and surface emitters. However, it is also possible that one surface emitter is assigned to a group of photodiodes, or that one photodiode is assigned to a group of surface emitters. The surface emitters emit electromagnetic radiation in a direction towards the photodiodes, which means perpendicular to the main surface of the substrate where the photodiodes are arranged. That the photodiodes and the surface emitter are aligned can further mean that they overlap in lateral directions which run parallel to the main surface of the substrate. A wide range of output voltages can be obtained by respective scaling of photodiodes and surface emitters. In addition, the efficiency of the OVT is high because the photodiodes and the surface emitters are aligned.

The photodiodes in the array of photodiodes can be connected in series and/or in parallel to control the output voltage.

It is possible that at least some of the photodiodes are electrically switchable such that the output voltage can be controlled by activating or deactivating the respective photodiodes. In other words, the output voltage can be scaled based on the number of active photodiodes. Similarly, at least some of the surface emitters can be electrically switchable.

According to an embodiment, the emitter is further configured to emit electromagnetic radiation towards a scene, wherein the optical sensor is configured to capture electromagnetic radiation generated by the emitter and reflected from the scene.

In this context, the term “scene” may refer to the environment of the optoelectronic device, including people, objects and other elements located in that environment. The terms “scene”, “environment” and “object” may be used interchangeably hereinafter. That the emitter emits electromagnetic radiation towards a scene can mean that it emits electromagnetic radiation in an additional direction, in particular in a direction that is different from the direction in which the receiver is located. Thus, the emitter can have a dual purpose: On the one hand it is configured to illuminate the receiver in order to generate an output voltage for operation of the optical sensor. On the other hand it is configured to illuminate the scene. This can mean that the emitter has at least two light emitting surfaces, wherein one surface faces the receiver and the other surface faces the scene in front of the optoelectronic device. In other words, it is possible to use the emitter for illuminating the PV cells and to use the same emitter for flash-illuminating an object within the scene (e.g. in a LiDAR application). For example, a both-side emitting VCSEL (that can emit light both from top and bottom) can be used to both illuminate the PV array (i.e., powering up the OVT module) and also illuminate the object. The optical sensor can be a SPAD array, as outlined above. The optical sensor is configured to capture electromagnetic radiation emitted by the emitter and reflected from the scene. The optoelectronic device can thus be implemented as camera device. By using only a single emitter for both illumination and voltage conversion the foot-print of the overall system can be further reduced.

Further, an optoelectronic system is provided. The optoelectronic system comprises the optoelectronic device as described above. This means that all features disclosed for the optoelectronic device are also disclosed for the optoelectronic system and vice-versa.

In an embodiment, the system comprises the optoelectronic device according to one of the above embodiments. The system further comprises a further emitter configured to emit electromagnetic radiation towards a scene, wherein the optical sensor is configured to capture electromagnetic radiation generated by the further emitter and reflected from the scene. The optoelectronic system can thus be implemented as camera system using two emitters including a dedicated emitter for illuminating the scene.

According to an embodiment, the optoelectronic device and the optoelectronic system, respectively, are implemented as time-of-flight depth sensor. A realization for using this solution is for Time-of-Flight (ToF) depth sensor in LiDAR applications, where the emitter illuminates an object and the reflected light back to the optical sensor (SPAD array) is detected. However, the OVT (i.e. emitter-receiver) in combination with the optical sensor (e.g. SPAD array) can be used in other applications beyond LiDAR, such as datacom, photon counting, etc.

Further, a method of manufacturing an optoelectronic device is provided. The method of manufacturing the optoelectronic device can preferably be employed for the optoelectronic device described above. This means that all features disclosed for the method are also disclosed for the optoelectronic device and vice-versa.

According to an embodiment, the method of manufacturing the optoelectronic device comprises providing an emitter that is operated with an electrical input voltage and configured to emit electromagnetic radiation during operation.

The method further comprises providing a receiver comprising at least one photodiode, and arranging the receiver such that it converts electromagnetic radiation emitted by the emitter to an output voltage. As explained above, this can mean that the receiver and the emitter are aligned to each other. For example, the emitter comprises a surface emitter and is arranged on top of the receiver, such that it emits light towards the receiver. It is further possible that the emitted electromagnetic radiation is forwarded to the receiver by wave-guiding or reflecting means.

The method further comprises providing an optical sensor comprising at least one avalanche photodiode, and arranging the optical sensor such that it is operated with the output voltage. The receiver and the optical sensor can be arranged next to each other and electrically connected by interconnects. Thus, the output voltage generated by the receiver can be used to power up the optical sensor.

The emitter-receiver system described here can advantageously be used as or be an optical voltage converter. The wide range of output voltages that can be generated from the OVT can be used to operate the optical sensor. Thus, charge pumps are not required. Further, by using the OVT as replacement for charge pumps a small foot-print can be achieved resulting in a compact device.

According to an embodiment, the method further comprises providing a substrate. The substrate may be a semiconductor substrate, in particular In (Ga) N, In (Ga) AlP, (Al) GaAs, (In) GaAs. Arranging the receiver and the optical sensor comprises forming the receiver and the optical sensor on a main surface of the substrate by epitaxial growth. This can mean that the receiver and the optical sensor are not mounted on the substrate but are integrally formed on the substrate to build a one-chip integration. In this embodiment, the optical sensor including the avalanche diode and the receiver including the photodiode are based on a similar III-V epitaxial structure. A same process flow can be used to build the optical sensor and the receiver. Thus, an integrated and compact device can be formed. This also simplifies packing and reduces the total cost per unit.

### BRIEF DESCRIPTION OF THE DRAWINGS

The following description of figures may further illustrate and explain aspects of the optoelectronic device, the optoelectronic system and the method of manufacturing the optoelectronic device. Components and parts of the optoelectronic device that are functionally identical or have an identical effect are denoted by identical reference symbols. Identical or effectively identical components, parts and steps might be described only with respect to the figures where they occur first. Their description is not necessarily repeated in successive figures.

FIG. 1 shows an optical sensor comprised by an optoelectronic device according to an embodiment.

FIG. 2 shows a current-voltage characteristic of an avalanche photodiode.

FIG. 3 shows a schematic of an optoelectronic device according to an embodiment.

FIG. 4 shows a top-view of an optoelectronic device according to an embodiment.

FIG. 5 shows a cross-section of an optoelectronic device according to an embodiment.

FIG. 6 shows a cross-section of an optoelectronic system according to an embodiment.

FIG. 7 schematically shows a method of manufacturing and/or operating an optoelectronic device according to an embodiment.

### DETAILED DESCRIPTION

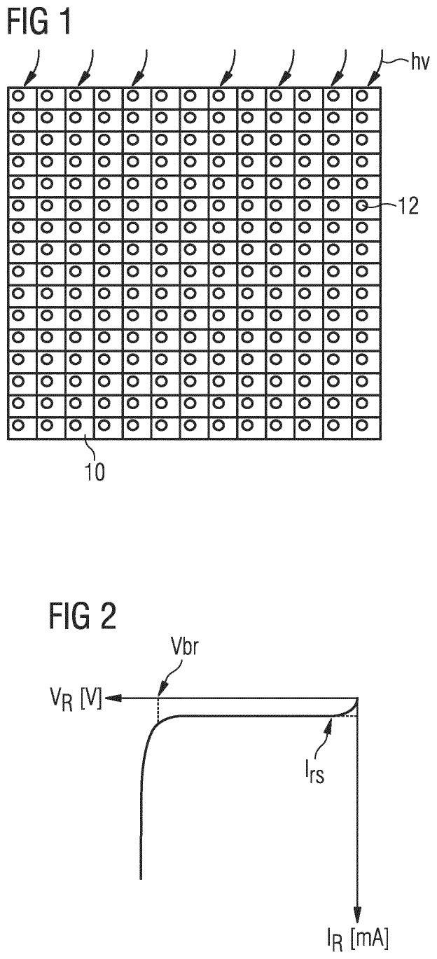

In FIG. 1 an optical sensor 10 is shown. The optical sensor 10 may be comprised by an optoelectronic device according to an embodiment. The optical sensor 10 according to FIG. 1 comprises a two-dimensional array of pixels. Each pixel comprises a photodetector, which is an avalanche photodiode 12. In particular, each avalanche photodiode 12 can be a single-photon avalanche diode, SPAD 12. The size of the array is arbitrary. The optical sensor 10 may further comprise additional components (not shown), for example a control circuit for activating/deactivating the pixels, a quenching circuit, a logic circuit for accumulating output signals from the pixels and/or a time-to-digital converter, TDC. The optical sensor 10 is configured to capture electromagnetic radiation hv, as indicated in FIG. 1. Thus, the optical sensor 10 may be configured to generate an image of a scene in front of the optical sensor 10. For example, the optical sensor 10 is implemented as time-of-flight sensor.

In FIG. 2 a current-voltage characteristic of an avalanche photodiode 12, APD 12, is shown. An APD, including SPAD, is a type of photodiode that operates in reverse bias and uses avalanche multiplication to amplify the photocurrent. The characteristic of FIG. 2 is a plot of the APD's current I_{R} (in mA) versus the applied reverse voltage V_{R} (in V). The current-voltage (I-V) characteristic of an avalanche photodiode is similar to that of a regular p-n junction diode, with a gradual increase in reverse current I_{R} with increasing reverse voltage V_{R} until the breakdown voltage V_{br} is reached, beyond which the current rapidly increases due to avalanche multiplication. In the reverse bias region below the breakdown voltage V_{br}, the current I_{R} of the APD 12 is primarily due to thermally generated carriers, which increase with temperature and reverse bias voltage V_{R} according to the diode equation. The current is typically negligible until the reverse voltage V_{R} exceeds the threshold voltage of the diode. Below the breakdown voltage V_{br} the current may be referred to a reverse saturation current Iᵣₛ. Once the reverse voltage Vᵣ reaches the breakdown voltage V_{br}, the electric field becomes strong enough to ionize some of the atoms in the depletion region, leading to the generation of electron-hole pairs. These additional carriers are then accelerated by the electric field and generate even more carriers through impact ionization, leading to an exponential increase in current with increasing voltage. The current-voltage curve of an APD typically shows a sharp knee or “turn-on” point at the breakdown voltage V_{br}, beyond which the current increases rapidly with increasing voltage. This characteristic is due to the positive feedback mechanism of avalanche multiplication, which causes a single electron or hole to trigger an avalanche of many more carriers. APDs 12 can be operated in either linear or Geiger mode. In linear mode, the APD is biased below the breakdown voltage V_{br}, and the output current is proportional to the incident light intensity. In Geiger mode, the APD is biased above the breakdown voltage V_{br}, and the avalanche process leads to a large output pulse for each detected photon. Geiger mode APDs are often used in applications requiring single photon detection. In this case, the APD 12 may be referred to as SPAD 12.

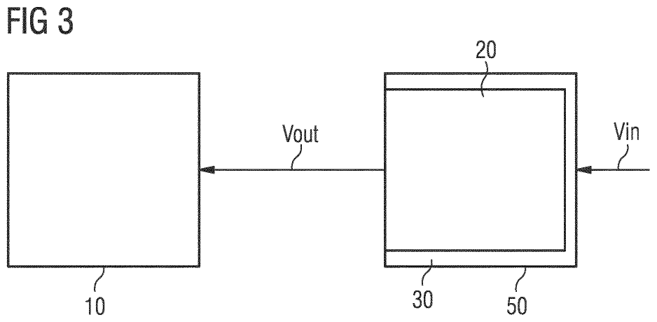

In FIG. 3 a schematic of an optoelectronic device according to an embodiment is shown. The optoelectronic device comprises an emitter 30 that is operated with an electrical input voltage Vin. The emitter 30 is configured to emit electromagnetic radiation 99 (not shown) during operation. The optoelectronic device further comprises a receiver 20 comprising at least one photodiode 22 (not shown), the receiver 20 being configured to convert electromagnetic radiation 99 emitted by the emitter 30 to an output voltage Vout. Further, the optoelectronic device comprises an optical sensor 10 comprising at least one avalanche photodiode 12 wherein the optical sensor 10 is operated with the output voltage Vout. For example, the optical sensor 10 comprises an array of APDs 12 as shown in FIG. 1.

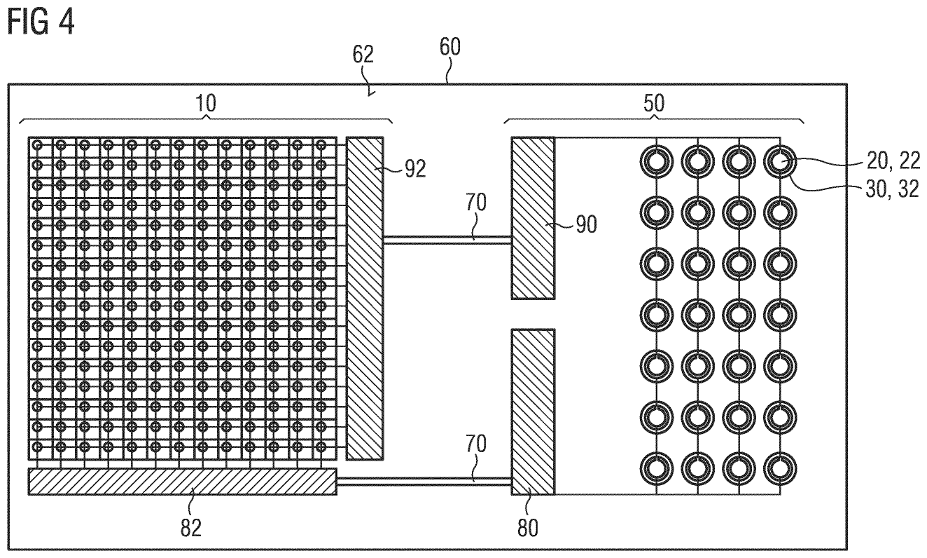

In FIG. 4 the optoelectronic device is shown in a top-view. The emitter 30, the receiver 20 and the optical sensor 10 are arranged on a main surface 62 of a substrate 60. The substrate 60 may comprise a semiconductor material, in particular a III-V compound semiconductor. The substrate 60 may be electrically insulating. For example, the substrate 60 is a semi-insulating GaAs substrate 60.

In the shown example of FIG. 4 the emitter 30 comprises a plurality of surface emitters 32, and the receiver 20 comprises a plurality of photodiodes 22. The photodiodes 22 and the surface emitters 32 each are arranged in an array. The photodiodes 22 and the surface emitters 32 are arranged in a stacked manner. In particular, each photodiode 22 is assigned to and aligned with a respective surface emitter 32. The photodiodes 22 are electrically arranged in series and in parallel. The array of photodiodes 22 forms columns of photodiodes 22, wherein the photodiodes 22 within each column are electrically connected in series. The columns are electrically connected in parallel. The array of surface emitters 32 may be arranged in a similar or different way. As mentioned above, the emitter 30 is operated with an input voltage Vin such that it generates electromagnetic radiation of a certain intensity. Each surface emitter 32 of the emitter 30 emits electromagnetic radiation towards a respective photodiode 22 of the receiver 20. The photodiodes 22 convert electromagnetic radiation into an output voltage Vout. Each photodiode 22 may convert a portion of the electromagnetic radiation emitted by the emitter 30 into a portion of the output voltage Vout. Thus, the emitter 30 and the receiver 20 form an optical voltage converter 50. Depending on the wiring of the surface emitters 32 and the photodiode 22 the input voltage Vin can be less or larger than the output voltage Vout. For example, if at least some of the photodiodes 22 are electrically connected in series, individual voltages add up to a high total voltage, such that the input voltage Vin can be less than the output voltage Vout. If at least some of the surface emitters 32 are electrically connected in series, the input voltage Vin can be larger than the output voltage Vout.

As shown in FIG. 4, the output voltage Vout is tapped at respective electrical terminals 80, 90 of the optical voltage converter 50. A first branch of electrical connections of the receiver 20 leads to a first electrical terminal 80, which may be, for example, a cathode terminal 80. A second branch of electrical connections of the receiver 20 leads to a second electrical terminal 90, which may be, for example, an anode terminal 90. Interconnects 70 on the main surface 62 of the substrate 60 electrically connect the anode and cathode terminals of the receiver 20 to respective electrical terminals 82, 92 of the optical sensor 10. Each pixel of the optical sensor 10 is electrically connected to both terminals 82, 92, as shown in FIG. 4. Thus, the optical sensor 10 is operated with the output voltage Vout generated by the receiver 20 by conversion of electromagnetic radiation emitted by the emitter 30.

In FIG. 5 a cross-section of the optoelectronic device is shown. It can be seen that the receiver 20 and the optical sensor 10 are in direct contact with the main surface 62 of the substrate 60. In particular, the receiver 20 and the optical sensor 10 may be integrated on the main surface 62, such that they form one single die. Further, the interconnects 70 are also arranged on the main surface 62 of the substrate 60 and electrically connect the receiver 20 to the optical sensor 10 for providing the output voltage Vout to the optical sensor 10 as shown in FIG. 4.

On top of the receiver 20 an optical component 40 is arranged. The optical component 40 is configured to direct electromagnetic radiation 99 emitted by the emitter 30 towards the receiver 20. The optical component 40 may be implemented as gap between the receiver 20 and the emitter 30. However, the optical component 40 can also comprise a material transparent for the wavelength emitted by the emitter 30. For example, the optical component 40 is implemented as interposer structure, lens, lens array and/or diffuser. It should be understood that the emitter 30 can also be an edge emitter (e.g. edge emitting laser) that is arranged adjacent to the receiver 20, instead of being arranged on top of the receiver 20. In that case, however, electromagnetic radiation emitted by the emitter 30 has to be directed onto the receiver 20 that is usually implemented as “upward-looking” device. Thus, for example, the optical component 40 can also be implemented as a reflector or waveguide.

In the shown example according to FIG. 5 the emitter 30 is implemented as surface emitter. Further, the emitter 30 comprises two light emitting surfaces, wherein one surface faces the receiver 20 and the other surface faces a scene in front of the optoelectronic device.

Thus, the emitter 30 is configured to emit a portion of electromagnetic radiation 99 towards the receiver 20, and is further configured to emit another portion of electromagnetic radiation 99 towards the scene, as illustrated in FIG. 5. For example, part of the electromagnetic radiation 99 emitted towards the scene hits an objects 100, where this part is reflected back to the optoelectronic device. The optical sensor 10 is configured to capture electromagnetic radiation generated by the emitter and reflected from the scene/the object 100. Thus, the optoelectronic device can be implemented as time-of-flight depth sensor, wherein one single light source is used for both voltage conversion to power up the optical sensor 10 and illumination of the scene.

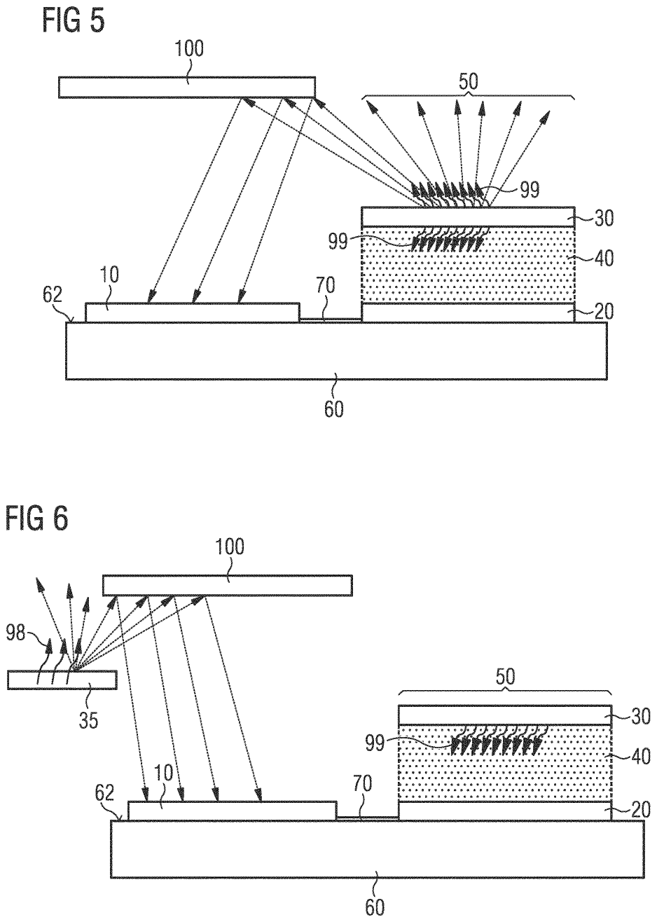

In FIG. 6 an optoelectronic system according to an embodiment is shown. The optoelectronic system differs from the optoelectronic device according to FIG. 5 in that the emitter 30 does not emit electromagnetic radiation on two sides of the emitter 30. Instead, only the receiver 20 is illuminated by the emitter 30. In order to illuminate the scene including the object 100 a further emitter 35 is comprised by the system. The further emitter 35 is configured to emit electromagnetic radiation 98 towards the scene, and the optical sensor 10 is configured to capture electromagnetic radiation 98 generated by the further emitter 35 and reflected from the scene/the object 100. The further emitter may be arranged on the substrate 60 or on a different carrier.

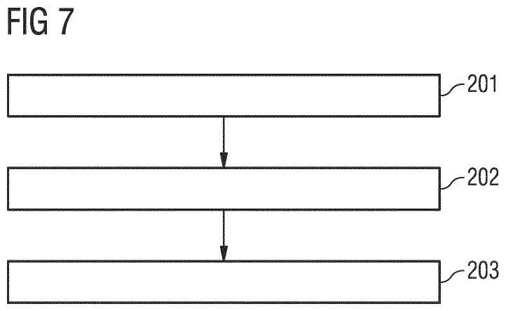

With FIG. 7 an exemplary embodiment of the method for manufacturing and/or operating the optoelectronic device is described. The method comprises the following steps that are not necessarily carried out in this order but can be carried out in this order.

In a first step 201 an emitter 30 is provided that is operated with an electrical input voltage Vin and configured to emit electromagnetic radiation 99 during operation.

In a second step 202 a receiver 20 is provided, the receiver 20 comprising at least one photodiode 22. Further, the receiver 20 is arranged such that it converts electromagnetic radiation 99 emitted by the emitter 30 to an output voltage Vout.

In a third step 203 an optical sensor 10 is provided that comprises at least one avalanche photodiode 12. Further the optical sensor 10 is arranged such that it is operated with the output voltage Vout.

The method may further comprise an additional step of providing a substrate 60. Providing and arranging the receiver 20 and providing and arranging the optical sensor 10 may comprise forming the receiver 20 and the optical sensor 10 on a main surface 62 of the substrate 60 by epitaxial growth. This can mean that both the receiver 20 and the optical sensor 10 are integrally formed on the main surface 62 of the substrate 60, e. g. during a same semiconductor process flow.

The embodiments of the optoelectronic device, the optoelectronic system and the method of manufacturing the optoelectronic device disclosed herein have been discussed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

This patent application claims the priority of U.S. provisional patent application 63/498,533, the disclosure content of which is hereby incorporated by reference.

### REFERENCES

10 optical sensor
12 avalanche photodiode
20 receiver
22 photodiode
30 emitter
32 surface emitter
35 further emitter
40 optical component
50 optical voltage transformer
60 substrate
62 main surface
70 interconnects
80 first electrical terminal of receiver
82 second electrical terminal of receiver
90 first electrical terminal of sensor
92 second electrical terminal of sensor
98 electromagnetic radiation from further emitter
99 electromagnetic radiation from emitter
100 object/scene
201 first step
202 second step
203 third step
Vin input voltage
Vout output voltage

1. An optoelectronic device, comprising:
an emitter, operated with an electrical input voltage and configured to emit electromagnetic radiation during operation;
a receiver comprising at least one photodiode, the receiver being configured to convert electromagnetic radiation emitted by the emitter to an output voltage; and
an optical sensor comprising at least one avalanche photodiode, wherein the optical sensor is operated with the output voltage.

2. The optoelectronic device according to claim 1, further comprising a substrate, wherein the receiver and the optical sensor are integrated on a main surface of the substrate.

3. The optoelectronic device according to claim 2, further comprising interconnects arranged on the main surface of the substrate and electrically connecting the receiver to the optical sensor for providing the output voltage to the optical sensor.

4. The optoelectronic device according to claim 2, wherein the substrate is electrically insulating.

5. The optoelectronic device according to claim 1, further comprising an optical component configured to direct electromagnetic radiation emitted by the emitter towards the receiver.

6. The optoelectronic device according to claim 1, wherein the emitter and the receiver are configured as an optical voltage converter for operating the optical sensor.

7. The optoelectronic device according to claim 1, wherein the electrical input voltage is less than the output voltage and the receiver comprises a plurality of photodiodes electrically connected in series.

8. The optoelectronic device according to claim 1, wherein the electrical input voltage is larger than the output voltage and the emitter comprises a plurality of surface emitters electrically connected in series.

9. The optoelectronic device according to claim 1, wherein the at least one avalanche photodiode of the optical sensor is a single-photon avalanche diode, SPAD.

10. The optoelectronic device according to claim 1, wherein the receiver comprises an array of photodiodes, and wherein the emitter comprises an array of surface emitters, wherein the emitter and the receiver being arranged on top of each other such that each photodiode is aligned with a respective surface emitter.

11. The optoelectronic device according to claim 1, wherein the emitter is further configured to emit electromagnetic radiation towards a scene, wherein the optical sensor is configured to capture electromagnetic radiation generated by the emitter and reflected from the scene.

12. An optoelectronic system comprising:
the optoelectronic device according to claim 1; and
a further emitter configured to emit electromagnetic radiation towards a scene, wherein the optical sensor is configured to capture electromagnetic radiation generated by the further emitter and reflected from the scene.

13. The optoelectronic system according to claim 12, wherein the optoelectronic system is implemented as time-of-flight depth sensor.

14. A method of manufacturing an optoelectronic device, the method comprising:
providing an emitter that is operated with an electrical input voltage and configured to emit electromagnetic radiation during operation;
providing a receiver comprising at least one photodiode, and arranging the receiver such that it converts electromagnetic radiation emitted by the emitter to an Output voltage;
providing an optical sensor comprising at least one avalanche photodiode; and
arranging the optical sensor such that it is operated with the output voltage.

15. The method according to claim 14, further comprising:
providing a substrate, and
forming the receiver and the optical sensor on a main surface of the substrate by epitaxial growth.

16. An optoelectronic device comprising:
an emitter, operated with an electrical input voltage and configured to emit electromagnetic radiation during operation;
a receiver comprising at least one photodiode, the receiver being configured to convert electromagnetic radiation emitted by the emitter to an output voltage; and
an optical sensor comprising at least one avalanche photodiode, wherein the optical sensor is operated with the output voltage, such that the at least one avalanche photodiode is reversed biased with the output voltage.
